(19) United States
(12) Patent Application Publication
(10) Pub. No.: US 2013/0333756 A1
(43) Pub. Date: Dec. 19, 2013

(54) BACKSHEET FOR A PHOTOVOLTAIC CELL MODULE AND PHOTOVOLTAIC CELL MODULE INCLUDING SAME

(71) Applicants: Richard A. DeLucca, Coatesville, PA (US); Yoshiaki Higuchi, Yokohama-shi (JP); Evan D. Laganis, West Chester, PA (US); Yasumasa Yukawa, Chiba-shi (JP)

(72) Inventors: Richard A. DeLucca, Coatesville, PA (US); Yoshiaki Higuchi, Yokohama-shi (JP); Evan D. Laganis, West Chester, PA (US); Yasumasa Yukawa, Chiba-shi (JP)

(21) Appl. No.: 13/527,112

(22) Filed: Jun. 19, 2012

(51) Int. Cl. H01L 31/0203; C08K 3/22; C08L 27/16; C08L 27/18; C08L 27/12; C08L 27/14; B32B 5/16; C08K 5/521

(52) U.S. Cl. 136/259; 428/220; 524/430; 524/140

(57) ABSTRACT

A backsheet (10) for use in a photovoltaic cell module (22) comprises a fluororesin (12) and a plurality of encapsulated particles (14) dispersed in the fluororesin (12). Each of the encapsulated particles (14) dispersed in the fluororesin (12) comprises a core particle (16), which comprises titanium dioxide (TiO₂). Each of the encapsulated particles (14) further comprises a metal oxide layer (18) disposed about the core particle (16). Further, each of encapsulated particles (14) also comprises an organic protective layer (20) disposed about the metal oxide layer (18). A photovoltaic cell module (22) comprising the backsheet (10) is also disclosed.

### BACKGROUND OF THE DISCLOSURE

1. Field of the Invention

The disclosure generally relates to a backsheet for a photovoltaic cell module and, more specifically, to a backsheet for a photovoltaic cell module comprising a fluororesin and a plurality of encapsulated particles dispersed therein. The disclosure also relates to a photovoltaic cell module including the backsheet.

2. Description of the Related Art

Photovoltaic cell modules are well known in the art and are generally utilized for converting solar radiation to electrical energy. Photovoltaic cell modules include a backsheet, which is an outermost layer of the photovoltaic cell modules. Photovoltaic cell modules further include a photovoltaic cell disposed on the backsheet, which is utilized for converting the solar radiation to electrical energy. The photovoltaic cell is typically encapsulated by an encapsulant layer. Finally, photovoltaic cell modules include a coversheet, typically formed from glass, such that the encapsulated layer including the photovoltaic cell is sandwiched between the backsheet and the coversheet. The coversheet is typically exposed to sunlight, which passes through the coversheet and the encapsulant layer to contact the photovoltaic cell.

Because backsheets are an outermost layer of photovoltaic cell modules, backsheets must have sufficient electrical insulation properties, moisture barrier properties, and longevity, with longevity being generally attributable to weather and heat resistance. For example, because photovoltaic cell modules are exposed to the elements for extended periods of time (e.g. up to several decades), the photovoltaic cell modules must be able to withstand the elements without deteriorating. Further, because photovoltaic cell modules are increasingly installed on the ground at an optimum angle for receiving sunlight (as opposed to being installed on a roof of a building), backsheets of photovoltaic cell modules also receive substantial sunlight depending on the location of the sun, which can undesirably cause deterioration and discoloration of conventional backsheets.

Conventional backsheets are typically formed from fluororesins or polyesters, e.g. polyethylene terephthalate (PET). In addition, many conventional backsheets are multi-laminated structures comprising a combination of layers and which often require the inclusion of a metal foil or polymeric barrier layer to prevent water permeation through the conventional backsheets, which can adversely impact the photovoltaic cell module. Such laminates generally require adhesives, which are also utilized to bond the backsheet and the remainder of the photovoltaic cell module. However, ultraviolet light deteriorates many adhesives, and thus it is desirable to minimize ultraviolet light transmittance of backsheets to prevent ultraviolet light from passing through the backsheets and deteriorating the adhesives.

White pigments, such as titanium oxide, have been relied upon in conventional backsheets to minimize the ultraviolet light transmittance of such conventional backsheets. However, such pigments must be utilized in relatively high concentrations, which add to costs associated with conventional backsheets, and which increase an average surface roughness of the conventional backsheets. In addition, when these pigments are utilized, the conventional backsheets typically must have a thickness of at least 25 micrometers (μm) to have any satisfactory physical properties, i.e., reducing the thickness of conventional backsheets cannot be done without sacrificing the physical properties and longevity of the conventional backsheets, which further adds to costs associated with conventional backsheets. Further, these pigments, particularly titanium dioxide, have photoactivity. This photoactivity of conventional titanium dioxide decomposes the fluororesin of the backsheet as the conventional titanium dioxide is irradiated by ultraviolet light, which is undesirable because such photoactivity may prematurely deteriorate the fluororesin itself and the backsheet of the photovoltaic cell modules.

### SUMMARY OF THE DISCLOSURE

The disclosure provides a backsheet for use in a photovoltaic cell module. The backsheet comprises a fluororesin and a plurality of encapsulated particles dispersed in the fluororesin. Each of the encapsulated particles dispersed in the fluororesin comprises a core particle, which comprises titanium dioxide (TiO₂). Each of the encapsulated particles further comprises a metal oxide layer disposed about the core particle. The metal oxide layer of the encapsulated particles comprises aluminum oxide. Each of encapsulated particles also comprises an organic protective layer disposed about the metal oxide layer. The organic protective layer is formed from an organic compound.

The disclosure also provides a photovoltaic cell module comprising the backsheet. The photovoltaic cell module further comprises a photovoltaic cell disposed adjacent the backsheet. In addition, the photovoltaic cell module comprises an encapsulant layer disposed on the photovoltaic cell such that the photovoltaic cell is sandwiched between the backsheet and the encapsulant layer. Finally, the photovoltaic cell module comprises a coversheet disposed adjacent the encapsulant layer such that the photovoltaic cell and the encapsulant layer are sandwiched between the backsheet and the coversheet.

The backsheet of the disclosure has excellent physical properties including, but not limited to, optical stability, thermal stability, photocatalytic stability, ultraviolet light transmittance, longevity, color stability, and moisture resistance. In fact, the backsheet of the disclosure has these excellent physical properties even while having a thickness that is less than a thickness of conventional backsheets, thus reducing costs associated with the preparation of the backsheet. Further, the backsheet of the disclosure even has these excellent physical properties at relatively low concentrations of the encapsulated particles as compared to conventional backsheets, which further reduces costs of the backsheet as compared to conventional backsheets.

### BRIEF DESCRIPTION OF THE DRAWINGS

Other advantages and aspects of this disclosure may be described in the following detailed description when considered in connection with the accompanying drawings wherein:

FIG. 1 is a schematic top view of a backsheet including a plurality of encapsulated particles;

FIG. 2 is a schematic cross-sectional view of an encapsulated particle; and

FIG. 3 is a schematic cross-sectional view of a photovoltaic cell module including the backsheet.

### DETAILED DESCRIPTION OF THE DISCLOSURE

Referring to the Figures, wherein like numerals indicate like parts throughout the several views, a backsheet in accordance with the instant disclosure is shown generally at 10. The backsheet 10 has excellent physical properties and is particularly suitable for photovoltaic cell modules. The instant disclosure also provides a photovoltaic cell module 22 including the backsheet 10.

The backsheet 10 comprises a fluororesin 12. The fluororesin 12 may be, for example, selected from the group of a polyvinyl fluoride polymer, a polyvinylidene fluoride polymer, a vinylidene fluoride/hexafluoropropylene copolymer, a tetrafluoroethylene/hexafluoropropylene/vinylidene fluoride type copolymer, a tetrafluoroethylene/propylene copolymer, a tetrafluoroethylene/hexafluoropropylene/propylene copolymer, an ethylene/tetrafluoroethylene type copolymer, an ethylene/chlorotrifluoroethlyene copolymer, a hexafluoropropylene/tetrafluoroethylene copolymer, a perfluoro(alkyl vinyl ether)/tetrafluoroethylene type copolymer, and combinations thereof. In certain embodiments, the fluororesin 12 is selected from the group of an ethylene/tetrafluoroethylene copolymer, an ethylene/chlorotrifluoroethlyene copolymer, a polyvinyl fluoride, a polyvinylidene fluoride, and combinations thereof. In other embodiments, the fluororesin 12 is selected from the group of an ethylene/tetrafluoroethylene copolymer, an ethylene/chlorotrifluoroethlyene copolymer, and combinations thereof. In one specific embodiment, the fluororesin 12 comprises an ethylene/tetrafluoroethylene copolymer, and in another specific embodiment, the fluororesin 12 comprises an ethylene/chlorotrifluoroethlyene copolymer.

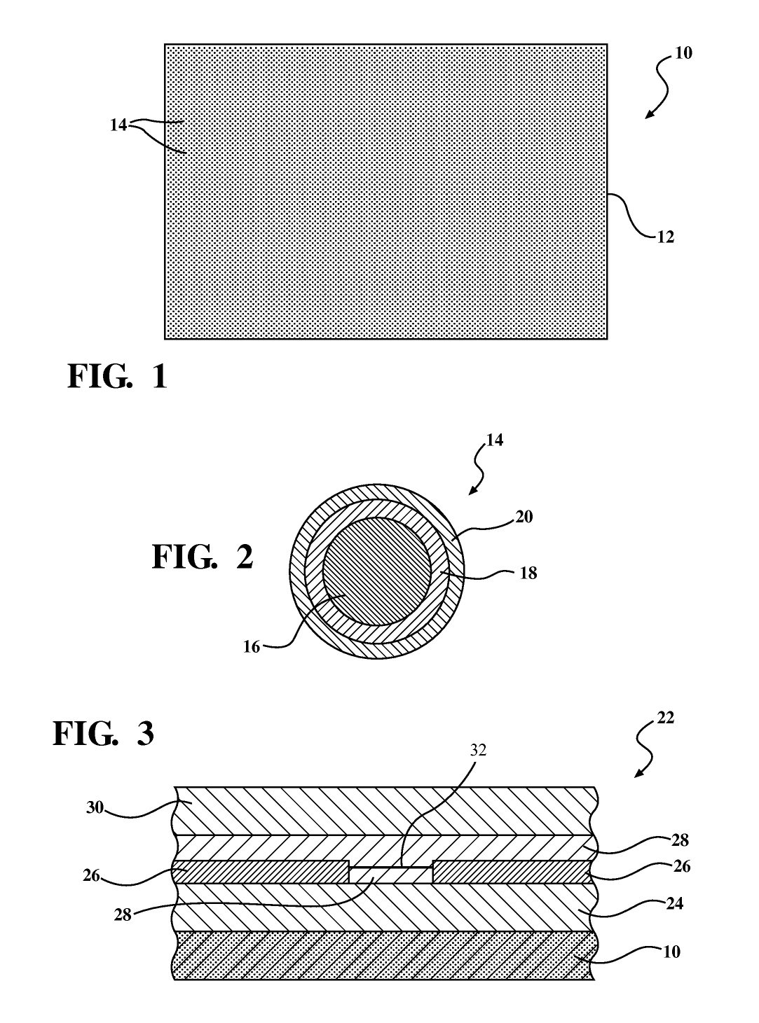

The backsheet 10 further comprises a plurality of encapsulated particles 14 dispersed in the fluororesin 12, as shown in FIG. 1. For purposes of clarity, the instant disclosure describes various aspects of typical encapsulated particles 14 suitable for the backsheet 10. However, some of the encapsulated particles 14 dispersed in the fluororesin of the backsheet 10 may be different from one another in terms of size, shape, and/or mass. To this end, the description below relative to the encapsulated particles 14 generally relates to average and typical attributes of the encapsulated particles 14 utilized in the backsheet 10, although particles different from those described below may also be utilized in conjunction with the encapsulated particles 14 in the backsheet 10.

As shown in FIG. 2, each of the encapsulated particles 14 comprises a core particle 16 comprising titanium dioxide (TiO₂). The encapsulated particles 14 further comprise a metal oxide layer 18 disposed about the core particle 16. In addition, the encapsulated particles 14 comprise an organic protective layer 20 disposed about the metal oxide layer 18.

The core particle 16 may comprise titanium dioxide (TiO₂), or the core particle 16 may comprise mica covered with titanium oxide or a pigment of a composite oxide containing titanium oxide. Most typically, however, the core particle 16 consists essentially of titanium dioxide (TiO₂), i.e., the core particle 16 comprises titanium dioxide (TiO₂) in an amount of at least about 95, alternatively at least about 96, alternatively at least about 97, alternatively at least about 98, alternatively at least about 99, alternatively at least about 99.9 percent by weight titanium dioxide (TiO₂) based on 100 parts by weight of the core particle. In other embodiments, the core particle 16 consists of titanium dioxide (TiO₂). The core particle 16 may have various shapes, e.g. the core particle 16 may be generally spherical or generally elliptical, or the core particle 16 may have an irregular shape. Typically, however, the core particle 16 is spherical.

The core particle 16 is typically a crystal of titanium dioxide (TiO₂), i.e., the core particle 16 comprises titanium dioxide (TiO₂) in a crystalline form. The crystalline form of the core particle 16 may independently be, for example, a rutile form, an anatase form, or a brookite form, because titanium dioxide (TiO₂) is polymorphic. Typically, however, the crystalline form of the core particle 16 is rutile form, which generally has a lower photoactivity than other crystalline forms of titanium dioxide (TiO₂). However, different encapsulated particles 14 may comprise different crystalline forms of titanium dioxide (TiO₂) as the core particle 16 in the backsheet 10 of the disclosure.

The metal oxide layer 18 of the encapsulated particles 14, which is disposed about the core particle 16 of titanium dioxide (TiO₂), comprises aluminum oxide. The aluminum oxide of the metal oxide layer 18 is typically aluminum(III) oxide (Al₂O₃), or alumina. In certain embodiments, the metal oxide layer 18 consists essentially of aluminum oxide. By “consists essentially of,” with reference to the metal oxide layer 18 consisting essentially of aluminum oxide, it is meant that nominal amounts of other metal oxides may be present along with the aluminum oxide in the metal oxide layer 18 so long as a majority of the metal oxide layer 18 comprises the aluminum oxide. For example, the aluminum oxide is typically present in the metal oxide layer 18 in an amount of from at least about 70, alternatively at least about 75, alternatively at least about 80, alternatively at least about 85, percent by weight based on the total weight of the metal oxides of the metal oxide layer.

Although other metal oxides may nominally be present along with the aluminum oxide in the metal oxide layer 18, in certain embodiments, the metal oxide layer 18 is substantially free of silicon dioxide (SiO₂). “Substantially free of,” with reference to the metal oxide layer 18 being substantially free of silicon dioxide (SiO₂), means that, if at all present, silicon dioxide (SiO₂) is present in the metal oxide layer 18 in an amount of less than about 5, alternatively less than about 4, alternatively less than about 3, alternatively less than about 2.5, alternatively less than about 2.25, percent by weight based on the total weight of the metal oxides present in the metal oxide layer 18.

When forming the metal oxide layer 18 on the core particle 16, aluminum oxide is typically utilized in an amount of from about 0.5 to about 2.9 parts by weight based on 100 parts by weight of the core particle 16. In one specific embodiment, aluminum oxide is utilized in an amount of from about 1.2 to about 1.4 parts by weight based on 100 parts by weight of the core particle 16. This weight basis relates solely to the aluminum oxide that actually forms the metal oxide layer 18, i.e., this weight basis does not include any residual aluminum oxide that remains after forming the metal oxide layer 18.

As noted above, the encapsulated particles 14 further comprise the organic protective layer 20, which is disposed about the metal oxide layer 18. The organic protective layer 20 is formed from an organic compound. The organic compound may be any organic compound suitable for forming the organic protective layer 20. For example, the organic compound may be a monomeric compound, an oligomeric compound, a polymeric compound, or combinations of such compounds, which may independently optionally have a reactive functionality. The organic compound may be reacted to form the organic protective layer 20, or the organic compound may adhere, bond, and/or otherwise be bound to the metal oxide layer 18 with or without reaction to form the organic protective layer 20. In the former embodiment, the organic protective layer 20 is a reaction product of the organic compound, whereas in the latter embodiment, the organic compound itself is bound to the metal oxide layer 18 to form the organic protective layer 20. When the organic compound is reactive, the organic compound may self polymerize or react to form the organic protective layer 20, or the organic compound may react with a surface functionality of the metal oxide layer 18. Alternatively, the organic compound may be physically bound to the metal oxide layer 18 without reaction. Said differently, the organic protective layer 20 may be chemically and/or physically bound to the metal oxide layer 18.

In various embodiments, the organic protective layer 20 is hydrophobic. Hydrophobicity of the organic protective layer 20 is generally imparted to the organic protective layer 20 via the organic compound. To this end, in such embodiments, the organic compound typically includes at least one lipophilic substituent.

In certain embodiments, the organic compound utilize to form the organic protective layer 20 is an organophosphate compound. As understood in the art, organophosphate compounds are generally esters of phosphoric acid. In particular, phosphoric acid can readily form triesters via esterification, in which organic groups are bonded to phosphorous via bivalent oxygen atoms. In such embodiments, the organophosphate compound may comprise a phosphate ester compound.

In certain embodiments in which the organic compound comprises the organophosphate compound, the organic compound has the following general formula:

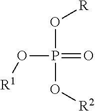

where R, R¹, and R² are independently selected from hydrogen and substituted or unsubstituted hydrocarbyl groups, with at least one of R, R¹, and R² being a substituted or unsubstituted hydrocarbyl group. Because it is desirable for the organic protective layer 20 to be hydrophobic, at least one of R, R¹, and R² is typically a lipophilic substituent, i.e., a long chain substituted or unsubstituted hydrocarbyl group. Typically, when R, R¹, and R² are all independently selected from substituted and unsubstituted hydrocarbyl groups, R, R¹, and R² are each aliphatic. R, R¹, and R² may be saturated or may include ethylenically unsaturated groups. Specific examples of R, R¹, and R² include aliphatic hydrocarbon groups having from 1 to 50 carbon atoms.

Depending on the desired physical properties of the organic protective layer 20, R, R¹, and R² may independently be short-chain aliphatic hydrocarbon groups, i.e., aliphatic hydrocarbon groups having from 1 to 5 carbon atoms, medium-chain aliphatic hydrocarbon groups, i.e., aliphatic hydrocarbon groups having from 6 to 12 carbon atoms, long-chain aliphatic hydrocarbon groups, i.e., aliphatic hydrocarbon groups having from 13 to 22 carbon atoms, and very long chain aliphatic hydrocarbon groups, i.e., aliphatic hydrocarbon groups having greater than 22 carbon atoms. As noted above, such aliphatic hydrocarbon groups may be saturated and unsaturated. Further, such aliphatic hydrocarbon group may optionally be substituted, e.g. the aliphatic hydrocarbon groups may optionally include at least one oxygen heteroatom within the chain.

Notably, the organic protective layer 20 may be formed from a plurality of organic compounds. In such an embodiment, each of the organic compounds utilized to form the organic protective layer 20 may differ from one another in terms of molecular structure. For example, the organic protective layer 20 may be formed from a plurality of organophosphate compounds, which may independently be selected from those described above such that R, R¹, and R² are the same or different not only within each organophosphate compound, but also the same or different relative to different organophosphate compounds utilized to form the organic protective layer 20.

In certain embodiments, the organic compound is utilized in an amount of from about 0.1 to about 1.0 parts by weight based on 100 parts of a combined weight of the core particle 16 and the metal oxide layer 18 to form the organic protective layer 20. This weight basis relates solely to the organic compound that actually forms the organic protective layer 20, i.e., this weight basis does not include any residual organic compound that remains after forming the organic protective layer 20 with the organic compound.

The metal oxide layer 18 and the organic protective layer 20 of the encapsulated particles 14 may each be uniform or non-uniform. For example, within a single encapsulated particle 14, the metal oxide layer 18 and/or the organic protective layer 20 may each have a varying thickness. Further, the metal oxide layer 18 and/or the organic protective layer 20 may each have varying thickness as between two or more encapsulated particles 14 utilized in the instant backsheet 10. Although the metal oxide layer 18 and/or the organic protective layer 20 may each have varying thickness, the metal oxide layer 18 and the organic protective layer 20 are generally continuously present in the encapsulated particles 14. Said differently, the metal oxide layer 18 typically encapsulates the core particle 16, and the organic protective layer 20 encapsulates the metal oxide layer 18.

The encapsulated particles 14 may optionally include additional layers between the core particle 16 and the metal oxide layer 18, between the metal oxide layer 18 and the organic protective layer 20, and/or disposed about the organic protective layer 20. However, in certain embodiments, the metal oxide layer 18 is disposed about and in contact with the core particle 16, and the organic protective layer 20 is disposed about and in contact with the metal oxide layer 18, with the organic protective layer 20 being an outermost layer of the encapsulated particles 14.

While the metal oxide layer 18 and the organic protective layer 20 of the encapsulated particles 14 may vary, the encapsulated particles 14 typically comprise titanium dioxide (TiO₂) in an amount of at least about 97 percent by weight based on the total weight of the encapsulated particles 14.

In certain embodiments, the encapsulated particles 14 have an average particle size of from about 0.1 to about 0.4, alternatively from about 0.15 to about 0.30, micrometers (μm). This average particle size relates to the encapsulated particles 14 themselves, i.e., this average particle size relates to the core particle 16 in combination with the metal oxide layer 18 and the organic protective layer 20. When the average particle size of the encapsulated particles 14 is less than about 0.1 micrometers (μm), the core particles 16 of the encapsulated particles 14 have relatively high surface to volume ratios, thereby requiring the metal oxide layers 18 and/or the organic protective layers 20 to be substantially thicker to obtain the desired water resistance properties and photocatalytic suppression properties. Alternatively, when the average particle size of the encapsulated particles 14 is greater than about 0.4 micrometers (μm), a minimum thickness of the backsheet 10 formed therewith is increased, which is undesirable. Said differently, when the average particle size of the encapsulated particles 14 is greater than about 0.4 micrometers (μm), the backsheets 10 formed therewith may be non-uniform at certain loadings of the encapsulated particles 14 and at certain thicknesses of the backsheet 10 (e.g. at ≦25 micrometers (μm)), which is undesirable.

The encapsulated particles 14 may be present in the backsheet 10 in varying concentrations contingent on the desired physical properties of the backsheet 10. In certain embodiments, the encapsulated particles 14 are present in the fluororesin 12 of the backsheet 10 in an amount of from about 2 to about 30, alternatively from about 4 to about 25, alternatively from about 6 to about 25, percent by weight based on the total weight of the backsheet 10. The remainder of the backsheet 10 is typically the fluororesin 12, although other components, pigments, fillers, or other compounds may also optionally be included along with the fluororesin 12 and the encapsulated particles 14 in the backsheet 10. When present in the backsheet 10 in such amounts, the encapsulated particles 14 impart the backsheet 10 with desirable physical properties even when the backsheet 10 has a comparatively small thickness. For example, when present in the backsheet 10 in such amounts, the encapsulated particles 14 have excellent dispersibility in the fluororesin 12, yet the backsheet 10 formed therewith has excellent ultraviolet light shielding properties, as reflected via the ultraviolet light transmittance values of the backsheet 10, as described below.

Notably, the encapsulated particles 14 may be compounded, e.g. kneaded, with the fluororesin 12 to prepare a concentrated compounded fluororesin. For example, because the encapsulated particles 14 have excellent dispersibility in the fluororesin 12, the encapsulated particles 14 may be compounded with the fluororesin 12 in an amount greater than that which is set forth above to prepare the concentrated compounded fluororesin, which can be sold or shipped and later diluted with additional fluororesin to a desired concentration of the encapsulated particles 14 to form the backsheet 10. To this end, the encapsulated particles 14 may be utilized to form the concentrated compounded fluororesin in an amount of from greater than about 25 percent by weight in the fluororesin, e.g. from greater than about 25 to about 75, alternatively from greater than about 25 to about 60, parts by weight based on 100 parts by weight of the concentrated compounded fluororesin.

The encapsulated particles 14 may be compounded with the fluororesin 12 in the absence of dispersing agents, which are typically utilized in conjunction with conventional pigments to improve dispersibility of the conventional pigments in conventional backsheets. However, the encapsulated particles 14 have excellent dispersibility, which is believed to be attributable to the organic protective layer 20 of the encapsulated particles 14, such that dispersing agents are not required when preparing the backsheet 10, although such dispersing agents may be utilized if desired.

The backsheet 10 may be formed via known methods. For example, the fluororesin 12 and the encapsulated particles 14 may be mixed or kneaded via an extruder and subsequently pelletized to form pellets which include the fluororesin 12 compounded with the encapsulated particles 14, i.e., a compounded fluororesin. The pellets can subsequently be extruded to form the backsheet 10. The encapsulated particles 14 are typically uniformly dispersed throughout the fluororesin 12 in the backsheet 10.

The backsheet 10 may have a uniform or non-uniform cross-sectional area and thickness, although typically the backsheet 10 has a uniform cross-sectional area and thickness. The thickness of the backsheet 10 is typically selected based on the desired physical properties of the backsheet 10 and the photovoltaic cell module 22 in which the backsheet 10 is to be employed. In certain embodiments, the backsheet 10 has an average thickness of from about 12 to about 100, alternatively about 12 to about 50, alternatively about 12 to about 30, micrometers (μm). The backsheet 10 of the disclosure maintains excellent physical properties at thicknesses as low as about 12 micrometers (μm), while conventional backsheets typically have a thickness of at least about 25 micrometers (μm). Moreover, as noted above, even at a thickness of about 25 micrometers (μm), the physical properties of conventional backsheets are significantly less desirable than the physical properties of the backsheet 10 even when the backsheet has a thickness of less than about 25 micrometers (μm).

The backsheet 10 typically has an inner face and an outer face, with both the inner face and outer face each presenting a surface. The outer face of the backsheet 10 is exposed to the elements when the backsheet 10 is incorporated into the photovoltaic cell module 22, while the inner face of the backsheet 10 is bonded to a remainder of the photovoltaic cell module 22. To this end, the outer face of the backsheet 10 may be matted to adjust the light diffusion properties of the backsheet 10 by adjusting a surface roughness of the outer face of the backsheet 10. In particular, the outer face of the backsheet 10 typically has a surface roughness of from greater than 0 to about 5, alternatively from about 0.1 to about 4, alternatively from about 0.2 to about 2.5, alternatively from about 0.6 to about 1.2, micrometers (μm), as stipulated by JIS B0601. Depending on a concentration of the encapsulated particles 14 in the backsheet 10, the surface roughness of the outer face of the backsheet 10 may be less than the range described above. In contrast, the surface roughness of conventional backsheets is typically minimized to obtain a uniform dispersion of any particles dispersed therein and to prevent surface cracking of the conventional backsheets. However, minimizing the surface roughness of the conventional backsheets sacrifices the light diffusion properties obtained from a matted, or rough, surface.

Conventional pigments utilized in conventional backsheets often comprise titanium oxide (TiO₂) encapsulated with silicon dioxide (SiO₂). The silicon dioxide (SiO₂) is utilized to encapsulate the titanium oxide (TiO₂) because the titanium oxide (TiO₂) has photoactivity, as described above, which can degrade the fluororesin 12 of the backsheet 10 as the titanium oxide (TiO₂) is irradiated with ultraviolet light. To this end, silicon dioxide (SiO₂) has been utilized to minimize and reduce the photoactivity of conventional titanium oxide (TiO₂) pigments. However, it has surprisingly been found that titanium oxide (TiO₂) and silicon dioxide (SiO₂) often include trace amounts of water, which is released by the conventional titanium oxide (TiO₂) pigments because silicon dioxide (SiO₂) and titanium oxide (TiO₂) each have moisture absorptivity. In particular, fluororesins generally have a comparatively high melting point temperature (e.g. of about 300° C. or higher), and thus when the conventional titanium oxide (TiO₂) pigments are introduced and mixed with the fluororesins at these temperatures, water is released from the conventional titanium oxide (TiO₂) pigments, which undesirably introduces bubbles and streaks in the conventional backsheets formed with such conventional titanium oxide (TiO₂) pigments. These problems associated with conventional backsheets including conventional titanium oxide (TiO₂) pigments are largely obviated via the backsheet 10 of the instant disclosure.

Further, as described above, the instant backsheet 10 has excellent physical properties, particularly as compared to conventional backsheets.

For example, the instant backsheet 10 has an excellent weight retention rate, which is calculated based on a weight of a compounded fluororesin at, for example, 30° C., and a weight of the compounded fluororesin at, for example, 400° C. At these temperatures, and at an average thickness of about 25 micrometers (μm), the instant backsheet 10 typically has a weight retention rate of at least about 95, alternatively at least about 96, alternatively at least about 97, alternatively at least about 98, alternatively at least about 99, alternatively at least about 99.2, percent, i.e., the compounded fluororesin utilized to form the backsheet generally retains much of its weight even while cycling to temperatures of about 400° C.

In addition, the backsheet 10 has excellent ultraviolet light shielding properties, even at very low concentrations of the encapsulated particles 14 in the backsheet 10. For example, ultraviolet light shielding properties are typically measured at a wavelength of 360 nanometers (nm) as stipulated by JIS R3106. The ultraviolet light shielding properties may alternatively be referred to as ultraviolet light transmittance. At an average thickness of about 25 micrometers (μm) and when the encapsulated particles 14 are utilized in an amount of at least about 6.25 percent by weight based on the total weight of the backsheet 10, the backsheet 10 typically has an ultraviolet light shielding properties of less than 1, alternatively less than about 0.2, alternatively less than about 0.1, alternatively less than about 0.08, alternatively less than about 0.06, alternatively less than about 0.04, alternatively no more than about 0.03, percent. The ultraviolet light shielding properties can be reduced to about 0 by including the encapsulated particles 14 in higher concentrations, e.g. in an amount of about 8.33 percent by weight based on the total weight of the backsheet 10 and up. To achieve such ultraviolet light shielding properties for conventional backsheets, conventional pigments are generally utilized in substantially higher concentrations, which add to the costs associated with the preparation of conventional backsheets.

Further, the instant backsheet 10 typically has excellent coloring resistance, even when subjected to recycling tests. For example, to determine coloring resistance, a color index for the backsheet 10 is measured via a color meter in reflective mode. Trimmings from the preparation of the backsheet 10 are recycled and extruded once again to form a recycled backsheet. The color index for the recycled backsheet is measured via the color meter in reflective mode. The color differential between the backsheet 10 and the recycled backsheet is calculated based on the respective color indices (i.e., the color index of the backsheet 10 and the color index of the recycled backsheet). This color differential is generally referred to as ΔE. It is desirable for ΔE to be less than about 1, and preferably ΔE is as small as possible. To this end, at an average thickness of about 25 micrometers (μm) and when the encapsulated particles 14 are utilized in an amount of about 6.25 percent by weight based on the total weight of the backsheet 10, the compounded fluororesin utilized to form the backsheet 10 has a ΔE of less than about 1, alternatively less than about 0.5, alternatively less than about 0.4, alternatively less than about 0.3, alternatively less than about 0.25, alternatively no more than about 0.20, which is desirable.

Additionally, the compounded fluororesin utilized to form the backsheet 10 has an excellent running volume. Running volume is calculated based on the volume of compounded fluororesin that can be extruded before a streak line appears which has a thickness that deviates by at least 2 micrometers (μm) relative to the adjoining portion of the backsheet 10. Generally, the streak line is attributable to a volatile content of the compounded fluororesins, which may build up in the extruder and be released through a film die of the extruder. The lesser the volatile content of the compounded fluororesin, the more material, i.e., compounded fluororesin, that can be extruded without interruption. To this end, the compounded fluororesin utilized to form the backsheet 10 generally has a running volume of at least about 8, alternatively at least about 9, alternatively at least about 10, alternatively at least about 11, alternatively at least about 12, metric tons.

Conventional backsheets have attempted to optimize certain physical properties with some success. However, the physical properties described above are mutually exclusive in the conventional backsheets, i.e., conventional backsheets do not simultaneously possess all of the excellent physical properties described above. For example, conventional backsheets may have a desirable ultraviolet light transmittance, but an undesirable ΔE, or vice versa. However, the instant backsheet 10 obviates these deficiencies of conventional backsheets and the instant backsheet 10 possesses such desirable physical properties simultaneously.

In fact, conventional backsheets typically have a thickness of from about 25 to about 30 micrometers (μm). However, the instant backsheet typically possesses the physical properties described above while having a thickness of less than 25 micrometers (μm), e.g. the instant backsheet may possess these physical properties while having a thickness of from about 12 to about 25 micrometers (μm). As such, not only are the physical properties of the instant backsheet 10 superior to those of conventional backsheets, but the instant backsheet 10 has superior physical properties as compared to conventional backsheets even while having a lesser thickness, thereby decreasing costs and imparting the photovoltaic cell module 22 including the backsheet 10 with desirable properties, e.g. flexibility.

As introduced above, the disclosure also provides a photovoltaic cell module 22 including the backsheet 10. The photovoltaic cell module 22 may be negatively or positively grounded. The photovoltaic cell module 22 can be of various shapes, sizes, and configurations and the photovoltaic cell module 22 is not limited to any particular shape, length or width.

As shown in FIG. 3, the photovoltaic cell module 22 comprises, in addition to the instant backsheet 10, a photovoltaic cell 26 disposed adjacent the backsheet 10. The photovoltaic cell module 22 also comprises an encapsulant layer 28 disposed on the photovoltaic cell 26 such that the photovoltaic cell 26 is sandwiched between the backsheet 10 and the encapsulant layer 28. Finally, the photovoltaic cell module 22 comprises a coversheet 30 disposed adjacent the encapsulant layer 28 such that the photovoltaic cell 26 and the encapsulant layer 28 are sandwiched between the backsheet 10 and the coversheet 30. Various aspects of the components of the photovoltaic cell module 22 are described in greater detail below, respectively.

The photovoltaic cell 26 is disposed adjacent the backsheet 10. The photovoltaic cell 26 may be disposed adjacent to and in contact with the backsheet 10, or the photovoltaic cell module 22 may further comprise an encapsulant layer 24 between the backsheet 10 and the photovoltaic cell 26 such that the photovoltaic cell 26 is disposed adjacent to but spaced from the backsheet 10. For example, the encapsulant layer 28 utilized between the photovoltaic cell 26 and the coversheet 30 may similarly be disposed between the backsheet 10 and the photovoltaic cell 26 such that the photovoltaic cell 26 is encapsulated by the encapsulant layer 24, 28. When the photovoltaic cell module 22 includes such an encapsulant layer 24 between the backsheet 10 and the photovoltaic cell 26, the encapsulant layer 24 may be the same as or different from the encapsulant layer 28 utilized between the photovoltaic cell 26 and the coversheet 30.

The photovoltaic cell module 22 may include one photovoltaic cell 26 or a plurality of photovoltaic cells 26. Typically, the photovoltaic cell module 22 includes a plurality of photovoltaic cells 26. When the photovoltaic cell module 22 includes the plurality of the photovoltaic cells 26, the photovoltaic cells 26 may be substantially coplanar with one another. Alternatively, the photovoltaic cells 26 may be offset from one another, e.g. the photovoltaic cells 26 may have a non-planar configuration. Regardless of whether the photovoltaic cells 26 are planar or non-planar with one another, the photovoltaic cells 26 may be arranged in various patterns, such as in a grid-like pattern, and adjacent photovoltaic cells 26 are typically connected via a tabbing ribbon 32.

The photovoltaic cells 26 may independently have various dimensions, be of various types, and be formed from various materials. The photovoltaic cells 26 may comprise any suitable material, e.g. the photovoltaic cells 26 may independently comprise monocrystalline silicon, polycrystalline silicon, amorphous silicon, nanocrystalline silicon, cadmium telluride (CdTe), copper indium gallium selenide (CIGS), etc. The photovoltaic cells 26 may have various thicknesses, such as from about 50 to about 250, alternatively from about 100 to about 225, alternatively from about 175 to about 225, alternatively about 180, micrometers (μm) on average. The photovoltaic cells 26 may independently have various widths and lengths.

The encapsulant layer 24, 28 utilized to protect the photovoltaic cell 26 may comprise encapsulant layers known in the art. For example, the encapsulant layer 24, 28 may be formed from ethylene vinyl acetate (EVA), which is a copolymer of ethylene and vinyl acetate. Alternatively, the encapsulant layer 24, 28 may be formed from a silicone composition, e.g. a hydrosilylation-reaction curable silicone composition.

The encapsulant layer 24, 28 can have various thicknesses, such as from about 0.125 to about 0.75, alternatively from about 0.2 to about 0.5, alternatively from about 0.25 to about 0.45, millimeter (mm), on average. Further, as set forth above, the photovoltaic cell module 22 may also include an encapsulant layer 24 between the backsheet 10 and the photovoltaic cell 26 such that the photovoltaic cell 26 is fully encapsulated by the encapsulant layer 24, 28. The encapsulant layer 24, 28 may be uniform or non-uniform and the encapsulant layer 24, 28 may vary between the photovoltaic cell 26 and the coversheet 30 and/or between the photovoltaic cell 26 and the backsheet 10.

The coversheet 30 has a front face and a rear face spaced from the front face. The coversheet 30 may be substantially planar or non-planar. The coversheet 30 is useful for protecting the photovoltaic cell module 22 from environmental conditions such as rain, snow, dirt, heat, etc. Typically, the coversheet 30 is optically transparent. The coversheet 30 is generally the sun side or front side of the photovoltaic cell module 22.

The coversheet 30 can be formed from various materials, as readily understood in the art. In certain embodiments, the coversheet 30 is formed from glass. Various types of glass can be utilized as the coversheet 30, such as silica glass, polymeric glass, borosilicate glass, etc. In addition, the coversheet 30 may be formed from a combination of different materials. The coversheet 30 may have portions formed from one material, e.g. glass, and other portions formed from another material, e.g. a polymeric material.

The coversheet 30 can have various thicknesses, such as from about 0.5 to about 10, about 1 to about 7.5, about 2.5 to about 5, or about 3, millimeters (mm), on average. The thickness of the coversheet 30 may be uniform or may vary.

If desired, the photovoltaic cell module 22 may further comprise a barrier layer (not shown) along with the backsheet 10 to further prevent water migration into the photovoltaic cell module 22. Such a barrier layer may be formed from, for example, a metal or alloy or from a polymeric material. When present in the photovoltaic cell module 22, the barrier layer is typically disposed on the inner face of the backsheet 10 such that the barrier layer is disposed adjacent to and in contact with the encapsulant layer 24 of the photovoltaic cell module 22, depending on the configuration of the photovoltaic cell module 22.

More than one photovoltaic cell module 22, i.e., plurality of photovoltaic cell modules, including the instant backsheet 10 may be utilized in concert with one another. Such a plurality of photovoltaic cell modules is generally referred to as an array. The array may be planar or non-planar. The photovoltaic cell module and/or the array may be used for various applications, such as for structures, buildings, vehicles, devices, vacant land, etc.

The photovoltaic cell module 22 has excellent physical properties attributable to the backsheet 10, and the physical properties of the backsheet 10 are described and introduced above, and further illustrated below in the Examples.

It is to be understood that the appended claims are not limited to express and particular compounds, compositions, or methods described in the detailed description, which may vary between particular embodiments which fall within the scope of the appended claims. With respect to any Markush groups relied upon herein for describing particular features or aspects of various embodiments, it is to be appreciated that different, special, and/or unexpected results may be obtained from each member of the respective Markush group independent from all other Markush members. Each member of a Markush group may be relied upon individually and or in combination and provides adequate support for specific embodiments within the scope of the appended claims.

It is also to be understood that any ranges and subranges relied upon in describing various embodiments of the present invention independently and collectively fall within the scope of the appended claims, and are understood to describe and contemplate all ranges including whole and/or fractional values therein, even if such values are not expressly written herein. One of skill in the art readily recognizes that the enumerated ranges and subranges sufficiently describe and enable various embodiments of the present invention, and such ranges and subranges may be further delineated into relevant halves, thirds, quarters, fifths, and so on. As just one example, a range “of from 0.1 to 0.9” may be further delineated into a lower third, i.e., from 0.1 to 0.3, a middle third, i.e., from 0.4 to 0.6, and an upper third, i.e., from 0.7 to 0.9, which individually and collectively are within the scope of the appended claims, and may be relied upon individually and/or collectively and provide adequate support for specific embodiments within the scope of the appended claims. In addition, with respect to the language which defines or modifies a range, such as “at least,” “greater than,” “less than,” “no more than,” and the like, it is to be understood that such language includes subranges and/or an upper or lower limit. As another example, a range of “at least 10” inherently includes a subrange of from at least 10 to 35, a subrange of from at least 10 to 25, a subrange of from 25 to 35, and so on, and each subrange may be relied upon individually and/or collectively and provides adequate support for specific embodiments within the scope of the appended claims. Finally, an individual number within a disclosed range may be relied upon and provides adequate support for specific embodiments within the scope of the appended claims. For example, a range “of from 1 to 9” includes various individual integers, such as 3, as well as individual numbers including a decimal point (or fraction), such as 4.1, which may be relied upon and provide adequate support for specific embodiments within the scope of the appended claims.

The following examples are intended to illustrate the disclosure and are not to be viewed in any way as limiting to the scope of the disclosure.

### EXAMPLES

### Example 1

A backsheet is prepared in accordance with the instant disclosure. In particular, a fluororesin and a plurality of encapsulated particles are kneaded via a twin screw extruder to form a compounded fluororesin. The fluororesin comprises an ethylene/tetrafluoroethylene type copolymer. The encapsulated particles are described below in Table 1 with regard to their composition. The compounded fluororesin is pelletized to form pellets. The pellets of the compounded fluororesin are extruded through a film die onto stainless steel cast rollers to prepare the backsheet. This process is repeated three different times to prepare three different backsheets in accordance with the instant disclosure, with the difference between each of the three backsheets being a concentration of the encapsulated particles in the respective backsheet, as described below.

### Comparative Example 1

A conventional backsheet is prepared in accordance with the process described above relative to Example 1 except the encapsulated particles utilized in Example 1 are replaced with conventional encapsulated particles for Comparative Example 1. The conventional encapsulated particles are described below in Table 1 with regard to their composition. All other parameters of the process, including the particular fluororesin employed, are the same as in Example 1. This process is repeated three different times to prepare three different conventional backsheets, with the difference between each of the three conventional backsheets being a concentration of the conventional encapsulated particles in the respective backsheet, as described below.

### Comparative Example 2

A conventional backsheet is prepared in accordance with the process described above relative to Example 1 except the encapsulated particles utilized in Example 1 are replaced with conventional encapsulated particles for Comparative Example 2 (which are also different from the conventional encapsulated particles utilized in Comparative Example 1). The conventional encapsulated particles are described below in Table 1 with regard to their composition. All other parameters of the process, including the particular fluororesin employed, are the same as in Example 1. This process is repeated three different times to prepare three different conventional backsheets, with the difference between each of the three conventional backsheets being a concentration of the conventional encapsulated particles in the respective backsheet, as described below.

TABLE 1

| | | Comparative | Comparative |
|---|---|---|---|
| Compound | Example 1 | Example 1 | Example 2 |
| TiO2 | 98.2 | 96.2 | 98.7 |
| Al2O3 | 1.28 | 1.21 | 0.68 |
| SiO2 | 0.03 | 2.52 | 0.26 |
| Organic | 0.15 | 0 | 0 |
| Other | 0.34 | 0.07 | 0.36 |

Table 1 above discloses the relative content of titanium dioxide, aluminum oxide, and silicon dioxide of the encapsulated particles of Example 1 and the conventional encapsulated particles of Comparative Examples 1 and 2. Further, Table 1 above discloses the relative content of any organic protective layer, which is present in the encapsulated particles of Example 1, but not in the conventional encapsulated particles of Comparative Examples 1 or 2. Finally, additional compounds that may be present, e.g. additional metal oxides other than aluminum oxide or silicon dioxide, in the encapsulated particles of Example 1 and Comparative Examples 1 and 2 are aggregated in the column entitled “other.” The quantitative values of Table 1 all relate to parts by weight based on 100 parts by weight of the respective encapsulated particles. These values were determined via literature and spectroscopy. For example, the composition of the encapsulated particles was determined as follows: atomic content was measured via a fluorescent X-ray analyzer; metal oxide content was measured via X-ray photoelectron spectroscopy; and functional elements were measured via infrared spectroscopy.

Physical Properties of the backsheets formed in Example 1 and Comparative Examples 1 and 2 are measured and set forth in Table 2 below. Notably, some of the physical properties set forth in Table 2 below relate to physical properties of the compounded fluororesins of Example 1 and Comparative Examples 1 and 2, i.e., some of the physical properties below do not necessarily relate to the backsheet form of the compounded fluororesins, although such physical properties would clearly correlate to the backsheet form of the compounded fluororesins.

Weight Retention Rate:

In particular, weight retention rate is calculated relative to compounded fluororesins of each of Example 1 and Comparative Examples 1 and 2 via a thermal gravimetric analyzer. More specifically, the respective compounded fluororesins are extruded and measured from 30 to 550° C. at a rate of 10° C. per minute in air which has a flow rate of 200 milliliters per minute (mL/min). The weight retention rate is calculated based on the weight of the respective compounded fluororesins at 30° C. (W₃₀) and 400° C. (W₄₀₀) in accordance with the following formula:

weight retention rate(%)=100×((W₄₀₀)/(W₃₀)).

It is desirable to have a weight retention rate close to 100, which means there is nominal or no weight loss.

Ultraviolet Light Transmittance:

The initial optical properties of the backsheet of Example 1 and the conventional backsheets of Comparative Examples 1 and 2 are measured. In particular, the ultraviolet light transmittance (%) at a wavelength of 360 nanometers (nm) is measured for each of these backsheets as stipulated by JIS R3106 with a UV-PC300 measuring apparatus. It is desirable for the ultraviolet light transmittance to be as small as possible.

Coloring:

Coloring from recycling is measured for the backsheet of Example 1 and the conventional backsheets of Comparative Examples 1 and 2. In particular, a color index for each of the respective backsheets is measured via a color meter in reflective mode (with each of the backsheets having a thickness of 25 micrometers (μm)). Trimmings from the preparation of each of the backsheets are recycled and extruded once again to form recycled backsheets (with each of the recycled backsheets also having a thickness of 25 micrometers (μm)). The color index for each of the recycled backsheets is measured via the color meter in reflective mode. The color differential between the backsheet and the recycled backsheet for each of Example 1 and Comparative Examples 1 and 2 is calculated based on the respective color indices (i.e., the color index of the backsheet and the color index of the recycled backsheet for each of these Examples). This color differential is generally referred to as ΔE. It is desirable for ΔE to be less than 1, and, preferably, ΔE is as small as possible.

Volume Resistivity:

Volume resistivity is measured for the backsheet of Example 1 and the conventional backsheets of Comparative Examples 1 and 2. In particular, volume resistivity is measured by a digital ultra-high resistance/micro current meter R8340 after a voltage of 500 volts (V) is applied to each of the backsheets. This is referred to in Table 2 below as the “initial” volume resistivity. The volume resistivity for each of the backsheets is also measured after the backsheets are subjected to a weather resistance test for 5,000 hours, which is referred to as “SWM” in Table 2 below. The weather resistance test utilizes a sunshine weather meter (Sunshine 300) with a black panel temperature of 63° C. Further, the volume resistivity for each of the backsheets is also measured after the backsheets are subjected to a heat resistance test at 230° C. for 168 hours, which is referred to as “HTT” in Table 2 below.

Tensile Strength and Breaking Elongation:

Tensile strength and breaking elongation are measured for the backsheet of Example 1 and the conventional backsheets of Comparative Examples 1 and 2. In particular, samples of the backsheets are obtained by cutting the backsheets into a sample size of 7×15 centimeters (cm). The samples are then placed into a gear oven with a rotating specimen rack. A dumbbell specimen is punched out of each of the samples in a shape in accordance with ASTM D638 Type V, and the breaking strength (MPa) and the breaking extension (%) in the machine direction and the transverse direction are measured. The average values of the machine direction and the transverse direction are regarded as the tensile strength and the breaking elongation, respectively. The values are calculated after subjecting the samples to the weather resistance test and the heat resistance test described above relative to volume resistivity.

Running Volume:

A running volume of material measures the amount of the compounded fluororesin utilized in Example 1 and Comparative Examples 1 and 2 that can be extruded to form the backsheets until a streak line appears. In particular, the compounded fluororesins are continuously extruded until a streak line appears which has a lesser thickness by at least 2 micrometers as compared with the adjoining thickness of the backsheet, and the total volume of the respective compounded fluororesins prior to the appearance of such a streak line in the backsheets is calculated. Generally, the streak line is attributable to the volatile content of the compounded fluororesins, which may build up in the extruder and be released through the film die of the extruder. The lesser the volatile content of the compounded fluororesins, the more material, i.e., compounded fluororesin, can be run, i.e., extruded, without interruption.

TABLE 2

| | | Concentration | | | |
|---|---|---|---|---|---|
| | | of Encapsulated | | Comparative | Comparative |
| Physical Property | | Particles | Example 1 | Example 1 | Example 2 |
| Weight retention rate (%) | | 20 | 99.45 | 99.05 | 99.5 |
| Initial Optical | 360 nm | 6.25 | 0.02 | 0.10 | 0.01 |
| Properties | transmittance | 8.33 | 0.00 | 0.01 | 0.00 |
| Colored by | ΔE After | 8.33 | 0.2 | 0.1 | 2.3 |
| Recycling | Recycling | | | | |
| Volume Resistivity | Initial | 8.33 | 460 | 450 | 470 |
| (10¹³ Ω · cm) | After SWM | 8.33 | 460 | 450 | 460 |
| | After HTT | 8.33 | 450 | 450 | 470 |
| Tensile Strength | Initial | 8.33 | 67 | 65 | 64 |
| (MPa) | After SWM | 8.33 | 66 | 65 | 65 |
| | After HTT | 8.33 | 50 | 47 | 48 |
| Breaking | Initial | 8.33 | 330 | 350 | 365 |
| Elongation (%) | After SWM | 8.33 | 335 | 350 | 360 |
| | After HTT | 8.33 | 305 | 310 | 320 |

| | | | | |
|---|---|---|---|---|
| Running Volume (metric ton) | 8.33 | 12.3 | 8.7 | unknown |

As evidenced in Table 2 above, the backsheet prepared in accordance with the instant disclosure (i.e., that of Example 1) has substantially better physical properties than the conventional backsheets prepared in accordance with Comparative Examples 1 and 2. While the conventional backsheets prepared in accordance with Comparative Examples 1 and 2 have certain desirable physical properties, such conventional backsheets do not simultaneously have numerous desirable physical properties. For example, the ultraviolet light transmittance of the backsheet of Example 1 at a concentration of encapsulated particles of merely 6.25 percent by weight corresponds roughly to the ultraviolet light transmittance of the conventional backsheet of Comparative Example 1 when the conventional backsheet of Comparative Example 1 has a concentration of conventional encapsulated particles of 8.33 percent by weight, i.e., the instant backsheet of Example 1 has similar ultraviolet light transmittance to the conventional backsheet of Comparative Example 1 while having a lower concentration of encapsulated particles, thereby decreasing the cost of the instant backsheet as compared to the conventional backsheet of Comparative Example 1. The conventional backsheet of Comparative Example 1 has an ultraviolet light transmittance that is 5 times, or 500%, greater than the backsheet of Example 1 when the conventional backsheet of Comparative Example 1 also has a concentration of encapsulated particles of 6.25 percent by weight. On the other hand, while the conventional backsheet of Comparative Example 2 has a desirable ultraviolet light transmittance, the conventional backsheet of Comparative Example 2 has a ΔE of 2.3, which is more than 11 times, or 1,100%, the ΔE of the backsheet of Example 1. Further, the compounded fluororesin of Example 1 has a running volume nearly 50 percent greater than that of Comparative Example 1. Accordingly, it is clear from Table 2 that the instant backsheet possess significantly superior physical properties as compared to the conventional backsheets of Comparative Examples 1 and 2.

### Example 2

A backsheet is prepared in accordance with the instant disclosure and pursuant to the process of Example 1. However, in Example 2, the encapsulated particles are utilized in an amount of 25 parts by weight based on 100 parts by weight of the backsheet. All other parameters of the process, including the particular fluororesin and encapsulated particles utilized, are the same as in Example 1.

### Example 3

A backsheet is prepared in accordance with the instant disclosure and pursuant to the process of Example 1. However, in Example 3, the encapsulated particles are utilized in an amount of 32 parts by weight based on 100 parts by weight of the backsheet. All other parameters of the process, including the particular fluororesin and encapsulated particles utilized, are the same as in Example 1.

### Example 4

A backsheet is prepared in accordance with the instant disclosure and pursuant to the process of Example 1. However, in Example 4, the encapsulated particles are utilized in an amount of 40 parts by weight based on 100 parts by weight of the backsheet. All other parameters of the process, including the particular fluororesin and encapsulated particles utilized, are the same as in Example 1.

### Comparative Example 3

A conventional backsheet is prepared in accordance with the process described above relative to Example 1 except the encapsulated particles utilized in Example 1 are replaced with conventional encapsulated particles for Comparative Example 3. The conventional encapsulated particles are described below in Table 3 with regard to their composition. All other parameters of the process, including the fluororesin utilized, are the same as in Example 1.

### Comparative Example 4

A conventional backsheet is prepared in accordance with the process described above relative to Example 1 except the encapsulated particles utilized in Example 1 are replaced with conventional encapsulated particles for Comparative Example 4. The conventional encapsulated particles are described below in Table 3 with regard to their composition. All other parameters of the process, including the fluororesin utilized, are the same as in Example 1.

### Comparative Example 5

A conventional backsheet is prepared in accordance with the process described above relative to Example 1 except the encapsulated particles utilized in Example 1 are replaced with conventional encapsulated particles for Comparative Example 5. The conventional encapsulated particles are described below in Table 3 with regard to their composition. All other parameters of the process, including the fluororesin utilized, are the same as in Example 1.

### Comparative Example 6

A conventional backsheet is prepared in accordance with the process described above relative to Example 1 except the encapsulated particles utilized in Example 1 are replaced with conventional encapsulated particles for Comparative Example 6. The conventional encapsulated particles are described below in Table 3 with regard to their composition. All other parameters of the process, including the fluororesin utilized, are the same as in Example 1.

### Comparative Example 7

A conventional backsheet is prepared in accordance with the process described above relative to Example 1 except the encapsulated particles utilized in Example 1 are replaced with conventional encapsulated particles for Comparative Example 7. The conventional encapsulated particles are described below in Table 3 with regard to their composition. All other parameters of the process, including the fluororesin utilized, are the same as in Example 1.

### Comparative Example 8

A conventional backsheet is prepared in accordance with the process described above relative to Example 1 except the encapsulated particles utilized in Example 1 are replaced with conventional encapsulated particles for Comparative Example 8. The conventional encapsulated particles are described below in Table 3 with regard to their composition. All other parameters of the process, including the fluororesin utilized, are the same as in Example 1.

TABLE 3

| | Comparative | Comparative | Comparative | Comparative | Comparative | Comparative |
|---|---|---|---|---|---|---|
| Compound | Example 3 | Example 4 | Example 5 | Example 6 | Example 7 | Example 8 |
| TiO2 | 97 | 92 | unknown | 89 | 97 | 97 |
| Al2O3 | 1.7 | 3.2 | unknown | 3.5 | >0 | 0.9 |
| SiO2 | unknown | 3.5 | unknown | 6.5 | unknown | 0.04 |
| Organic | ≧0, hydrophilic | ≧0, hydrophobic | unknown | 0 | unknown | 0 |
| Other | unknown | unknown | unknown | 1 | unknown | 2.06 |

Table 3 above discloses the relative content of titanium dioxide, aluminum oxide, and silicon dioxide of the conventional encapsulated particles of Comparative Examples 3-8. Further, Table 3 above discloses the relative content of any organic content of the conventional encapsulated particles. Finally, additional compounds that may be present, e.g. additional metal oxides other than aluminum oxide or silicon dioxide, in the conventional encapsulated particles of Comparative Examples 3-8 are aggregated in the column entitled “other.” The quantitative values of Table 3 all relate to parts by weight based on 100 parts by weight of the respective encapsulated particles. These values were determined via literature and spectroscopy. For example, the composition of the encapsulated particles was determined as follows: atomic content was measured via a fluorescent X-ray analyzer; metal oxide content was measured via X-ray photoelectron spectroscopy; and functional elements were measured via infrared spectroscopy.

Physical properties of the backsheets of Examples 2-4 and Comparative Examples 3-8 are measured and set forth in Table 4 below. Notably, some of the physical properties set forth in Table 4 below relate to physical properties of the compounded fluororesins of Example 1 and Comparative Examples 1 and 2, i.e., some of the physical properties below do not necessarily relate to the backsheet form of the compounded fluororesins, although such physical properties would clearly correlate to the backsheet form of the compounded fluororesins. Each of the backsheets of Examples 2-4 and Comparative Examples 3-8 have an average thickness of 25 micrometers (μm).

CIELAB L:

CIELAB L is measured via a GretagMacbeth Color i5 spectrophotometer. CIELAB L measures a whiteness of the backsheets of Examples 2-4 and Comparative Examples 3-8, with a value of 100 indicating a perfect whiteness and a value of 0 indicating a perfect blackness.

CIELAB a:

CIELAB a is measured via a GretagMacbeth Color i5 spectrophotometer. CIELAB a measures a red/green color of the backsheets of Examples 2-4 and Comparative Examples 3-8, with a positive number corresponding to a red color and a negative number corresponding to a green color.

CIELAB b:

CIELAB b is measured via a GretagMacbeth Color i5 spectrophotometer. CIELAB b measures a yellow/blue color of the backsheets of Examples 2-4 and Comparative Examples 3-8, with a positive number corresponding to a yellow color and a negative number corresponding to a blue color.

Yellowness:

Yellowness is measured via a GretagMacbeth Color i5 spectrophotometer, in connection with CIELAB b.

Contrast Ratio:

Contrast ratio is measured via a GretagMacbeth Color i5 spectrophotometer. Contrast ratio indicates the opacity of the backsheets of Examples 2-4 and Comparative Examples 3-8, with a higher value corresponding to a higher level of opacity.

Surface Roughness:

Surface roughness is measured via a contact surface roughness meter. The value indicates the average variability of a surface of the backsheets of Examples 2-4 and Comparative Examples 3-8 from a perfect smoothness.

The measurements relating to ΔE and weight retention rate (or % retained at 400° C.) are described above with regards to Example 1 and Comparative Examples 1 and 2.

TABLE 4

| | Concentration of | | | | | | | | Surface |
|---|---|---|---|---|---|---|---|---|---|
| | Encapsulated | | | | | | Contrast | % Retained | Roughness |
| Example: | Particles | CIELAB L | CIELAB a | CIELAB b | ΔE | Yellowness | Ratio | at 400° C. | (μm) |
| Example 2 | 25 | 97.893 | −0.589 | 0.837 | — | 8.627 | 98.829 | 99.2 | 0.23 |
| Comparative | 25 | 95.513 | 0.072 | 4.874 | 4.733 | 16.102 | 99.980 | n/a | 0.46 |
| Example 3 | | | | | | | | | |
| Comparative | 25 | 97.081 | −0.303 | 2.704 | 2.056 | 12.057 | 99.480 | 98.17 | 0.63 |
| Example 4 | | | | | | | | | |
| Comparative | 25 | 91.393 | 0.548 | 6.671 | 8.808 | 19.903 | 100.334 | n/a | 0.93 |
| Example 5 | | | | | | | | | |
| Comparative | 25 | n/a | n/a | n/a | n/a | n/a | n/a | n/a | n/a |
| Example 6 | | | | | | | | | |
| Comparative | 25 | 95.224 | 0.028 | 5.232 | 5.179 | 16.694 | 99.934 | 98.66 | 0.5 |
| Example 7 | | | | | | | | | |
| Comparative | 25 | 92.384 | 0.615 | 6.270 | 7.831 | 19.164 | 98.442 | 98.86 | 0.68 |
| Example 8 | | | | | | | | | |
| Example 3 | 32 | 98.259 | −0.569 | 1.336 | 0.618 | 9.492 | 99.694 | n/a | 0.33 |
| Example 4 | 40 | 98.286 | −0.604 | 1.338 | 0.637 | 9.471 | 99.427 | n/a | 0.41 |

No data is available for Comparative Example 6 because the conventional encapsulated particles of Comparative Example 6 would not adequately disperse in the fluororesin and thus the compounded fluororesin was not suitable for extruding into a conventional backsheet. As clearly illustrated above in Table 4, the backsheet according to the instant disclosure has significantly superior physical properties as compared to the conventional backsheets including the conventional encapsulated particles. Surprisingly, Table 4 even illustrates that the backsheets of the instant disclosure have an average surface roughness that is less than the average surface roughness of the conventional backsheets of Comparative Examples 3-8 even when the backsheets of the instant disclosure have a concentration of encapsulated particles of 40 percent by weight and the conventional backsheets have a concentration of conventional encapsulated particles of merely 25 percent by weight.

What is claimed is:

1. A backsheet for use in a photovoltaic cell module, said backsheet comprising:
a fluororesin; and
a plurality of encapsulated particles dispersed in said fluororesin;
wherein each of said encapsulated particles comprises:
a core particle comprising titanium dioxide (TiO₂);
a metal oxide layer disposed about said core particle and comprising aluminum oxide; and
an organic protective layer disposed about said metal oxide layer with said organic protective layer being formed from an organic compound.

2. A backsheet as set forth in claim 1 wherein said metal oxide layer is substantially free of silicon dioxide (SiO₂).

3. A backsheet as set forth in claim 1 wherein said aluminum oxide is present in said metal oxide layer in an amount of at least about 80 percent by weight based on a total weight of any metal oxides present in said metal oxide layer.

4. A backsheet as set forth in claim 1 wherein said aluminum oxide is utilized in said metal oxide layer in an amount of from about 0.5 to about 2.9 parts by weight based on 100 parts by weight of said core particle.

5. A backsheet as set forth in claim 1 wherein said organic compound comprises an organophosphate compound.

6. A backsheet as set forth in claim 5 wherein said organophosphate compound comprises a phosphate ester compound.

7. A backsheet as set forth in claim 1 wherein said organic compound is utilized in an amount of from about 0.1 to about 1.0 parts by weight based on 100 parts of a combined weight of said core particle and said metal oxide layer to form said organic protective layer.

8. A backsheet as set forth in claim 1 having an average thickness of from about 12 to about 100 micrometers (μm).

9. A backsheet as set forth in claim 1 wherein said encapsulated particles have an average particle size of from about 0.1 to about 0.4 micrometers (μm).

10. A backsheet as set forth in claim 1 wherein said encapsulated particles are present in said fluororesin of said backsheet in an amount of from about 2 to about 30 percent by weight based on the total weight of said backsheet.

11. A backsheet as set forth in claim 1 wherein said encapsulated particles comprise titanium dioxide (TiO₂) in an amount of at least about 97 percent by weight based on the total weight of said encapsulated particles.

12. A backsheet as set forth in claim 1 wherein said fluororesin is selected from the group of an ethylene/tetrafluoroethylene copolymer, an ethylene/chlorotrifluoroethlyene copolymer, a polyvinyl fluoride, a polyvinylidene fluoride, and combinations thereof.

13. A backsheet as set forth in claim 1 wherein said fluororesin is selected from the group of an ethylene/tetrafluoroethylene copolymer, an ethylene/chlorotrifluoroethlyene copolymer, and combinations thereof.

14. A backsheet as set forth in any claim 1 wherein said fluororesin comprises an ethylene/tetrafluoroethylene copolymer.

15. A backsheet as set forth in claim 1 wherein said wherein said fluororesin comprises an ethylene/chlorotrifluoroethlyene copolymer.

16. A backsheet as set forth in claim 1 having an ultraviolet light transmittance (%) at a wavelength of 360 nanometers (nm) of no more than about 0.03.

17. A backsheet as set forth in claim 1 having a weight retention rate at 400° C. of at least about 99.2% when said encapsulated particles are present in said backsheet in an amount of 25 percent by weight based on the total weight of said backsheet.

18. Use of a backsheet in accordance with claim 1 in a photovoltaic cell module.

19. A photovoltaic cell module comprising:
a backsheet in accordance with claim 1;
a photovoltaic cell disposed adjacent said backsheet;
an encapsulant layer disposed on said photovoltaic cell such that said photovoltaic cell is sandwiched between said backsheet and said encapsulant layer; and
a coversheet disposed adjacent said encapsulant layer such that said photovoltaic cell and said encapsulant layer are sandwiched between said backsheet and said coversheet.

20. A photovoltaic cell module as set forth in claim 19 wherein said backsheet has an ultraviolet light transmittance (%) at a wavelength of 360 nanometers (nm) of no more than about 0.03.
